(19) United States
(12) Patent Application Publication
(10) Pub. No.: US 2024/0413149 A1
(43) Pub. Date: Dec. 12, 2024

(54) INTEGRATED CIRCUIT

(71) Applicant: TAIWAN SEMICONDUCTOR MANUFACTURING COMPANY, LTD., Hsinchu (TW)

(72) Inventors: Ching-Yu HUANG, Hsinchu City (TW); Wei-Cheng TZENG, Taipei City (TW); Chun-Yen LIN, Hsinchu City (TW); Shih-Wei PENG, Hsinchu City (TW); Kuan Yu CHEN, Hsinchu City (TW); Wei-Cheng LIN, Taichung City (TW); Jiann-Tyng TZENG, Hsinchu City (TW)

(73) Assignee: TAIWAN SEMICONDUCTOR MANUFACTURING COMPANY, LTD., Hsinchu (TW)

(21) Appl. No.: 18/331,023

(22) Filed: Jun. 7, 2023

(51) Int. Cl. H01L 27/088; H01L 29/08

(52) U.S. Cl. CPC H01L 27/088; H01L 29/0847

(57) ABSTRACT

An integrated circuit is provided which includes a first complementary field-effect transistor and a second complementary field-effect transistor. The first complementary field-effect transistor includes at least two first transistors respectively located on a first layer and a second layer. The second complementary field-effect transistor is disposed adjacent to the first complementary field-effect transistor. The second complementary field-effect transistor includes at least two second transistors respectively located on the first layer and the second layer. Type of one of the at least two first transistors located on the first layer is different from type of one of the at least two second transistors located on the first layer.

### BACKGROUND

Size of integrated circuits decrease day by day. Nano-sheet structures used in the integrated circuits suffer from occupying area. In addition, interconnections of complementary field-effect transistors (CFET) are complex which lead to high power consumption.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of part of an integrated circuit, in accordance with some embodiments of the present disclosure.

FIG. 2 is a schematic diagram of part of an integrated circuit, in accordance with some embodiments of the present disclosure.

FIG. 3 is a schematic diagram of part of an integrated circuit, in accordance with some embodiments of the present disclosure.

FIG. 4 is a top view and a bottom view diagram of part of an integrated circuit, in accordance with some embodiments of the present disclosure.

FIG. 5 is a block diagram illustrating of an electronic device design system, in accordance with one or more embodiments of the present disclosure.

FIG. 6 is a schematic diagram of part of a floor plan of an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

As used herein, the terms “comprising,” “including,” “having,” “containing,” “involving,” and the like are to be understood to be open-ended, i.e., to mean including but not limited to.

Reference throughout the specification to “one embodiment,” “an embodiment,” or “some embodiments” means that a particular feature, structure, implementation, or characteristic described in connection with the embodiment(s) is included in at least one embodiment of the present disclosure. Thus, uses of the phrases “in one embodiment” or “in an embodiment” or “in some embodiments” in various places throughout the specification are not necessarily all referring to the same embodiment. Furthermore, the particular features, structures, implementation, or characteristics may be combined in any suitable manner in one or more embodiments.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, the term “and/or” includes any and all combinations of one or more of the associated listed items.

As used herein, “around”, “about”, “approximately” or “substantially” shall generally refer to any approximate value of a given value or range, in which it is varied depending on various arts in which it pertains, and the scope of which should be accorded with the broadest interpretation understood by the person skilled in the art to which it pertains, so as to encompass all such modifications and similar structures. In some embodiments, it shall generally mean within 20 percent, preferably within 10percent, and more preferably within 5 percent of a given value or range. Numerical quantities given herein are approximate, meaning that the term “around”, “about”, “approximately” or “substantially” can be inferred if not expressly stated, or meaning other approximate values.

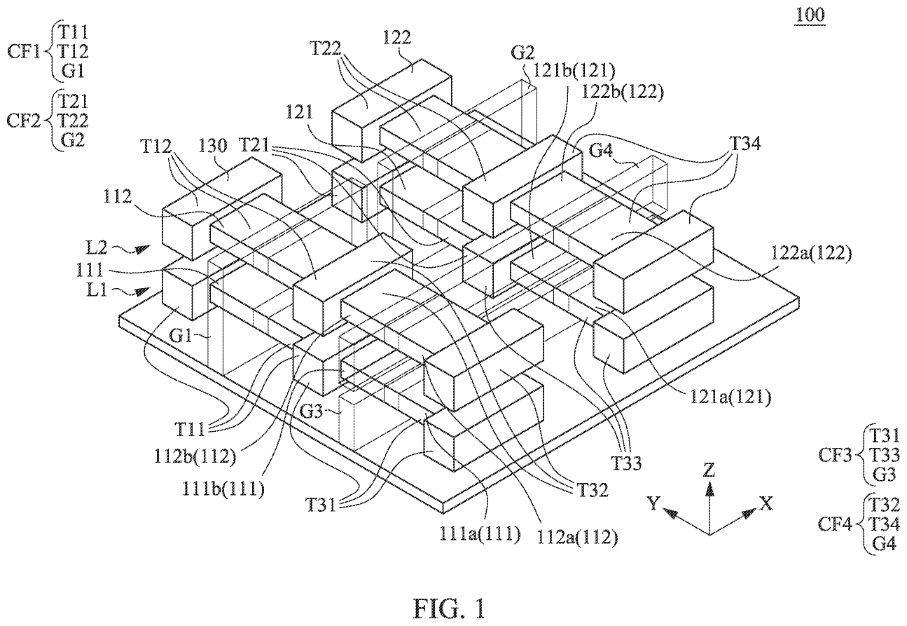

Reference is now made to FIG. 1. FIG. 1 is a schematic diagram of part of an integrated circuit 100, in accordance with some embodiments of the present disclosure. For illustration, the integrated circuit 100 includes a complementary field-effect transistor CF1 and a complementary field-effect transistor CF2.

In some embodiments, the complementary field-effect transistor CF1 is disposed adjacent to the complementary field-effect transistor CF2. For example, the complementary field-effect transistor CF2 is disposed at the right side of the complementary field-effect transistor CF1. In various embodiments, the complementary field-effect transistor CF1 is disposed directly adjacent to the complementary field-effect transistor CF2. For example, there is no other device, transistor, or structure disposed between the complementary field-effect transistor CF1 and the complementary field-effect transistor CF2.

In some embodiments, the complementary field-effect transistor CF1 includes at least two transistors T11, T12 respectively located on a layer L1 and a layer L2. The complementary field-effect transistor CF2 includes at least two transistors T21, T22 respectively located on the layer L1 and the layer L2. Alternatively stated, the transistor T12 is stacked with the transistor T11, and the transistor T21 is stacked with the transistor T22.

In some embodiments, type of one of the at least two transistors T11, T12 located on the layer L1 is different from type of one of the at least two transistors T21, T22 located on the layer L1. For example, type of the transistor T11 of the at least two transistors T11, T12 located on the layer L1 is different from type of the transistor T21 of the at least two transistors T21, T22 located on the layer L1. In various embodiments, the transistor T11 of the at least two transistors T11, T12 located on the layer L1 is P-type transistor, and the transistor T21 of the at least two transistors T21, T22 located on the layer L1 is N-type transistor.

In some embodiments, type of another one of the at least two transistors T11, T12 located on the layer L2 is different from type of another one of the at least two transistors T21, T22 located on the layer L2. For example, type of the transistor T12 of the at least two transistors T11, T12 located on the layer L2 is different from type of the transistor T22 of the at least two transistors T21, T22 located on the layer L2. In various embodiments, the transistor T12 of the at least two transistors T11, T12 located on the layer L2 is N-type transistor, and the transistor T22 of the at least two transistors T21, T22 located on the layer L2 is P-type transistor.

In some embodiments, type of one of the at least two transistors T11, T12 located on the layer L1 is the same as type of another one of the at least two transistors T21, T22 located on the layer L2. For example, type of the transistor T11 of the at least two transistors T11, T12 located on the layer L1 is the same as type of the transistor T22 of the at least two transistors T21, T22 located on the layer L2. In various embodiments, the transistor T11 of the at least two transistors T11, T12 located on the layer L1 is P-type transistor, and the transistor T22 of the at least two transistors T21, T22 located on the layer L2 is P-type transistor.

In some embodiments, type of another one of the at least two transistors T11, T12 located on the layer L2 is the same as type of one of the at least two transistors T21, T22 located on the layer L1. For example, type of the transistor T12 of the at least two transistors T11, T12 located on the layer L2 is the same as type of the transistor T21 of the at least two transistors T21, T22 located on the layer L1. In various embodiments, the transistor T12 of the at least two transistors T11, T12 located on the layer L2 is N-type transistor, and the transistor T21 of the at least two transistors T21, T22 located on the layer L1 is N-type transistor.

In some embodiments, the complementary field-effect transistor CF1 further includes a gate structure G1. The gate structure G1 corresponds to gates of the at least two transistors T11, T12. In various embodiments, the complementary field-effect transistor CF2 further includes a gate structure G2. The gate structure G2 corresponds to gates of the at least two transistors T21, T22.

The configurations of P-type and N-type transistors in the adjacent two complementary field-effect transistors CF1-CF2 are different. For example, as shown in FIG. 1, conductivity types of the at least two transistors T11, T12 are different. The transistor T11 of the at least two transistors T11, T12 is P-type transistor, and the transistor T12 of the at least two transistors T11, T12 is N-type transistor. Similarly, conductivity types of the at least two transistors T21, T22 are different. For example, the transistor T21 of the at least two transistors T21, T22 is N-type transistor, and the transistor T22 of the at least two transistors T21, T22 is P-type transistor. Alternatively stated, two adjacent transistors (e.g., the transistors T11 and T21) arranged in a same layer of the two adjacent two complementary field-effect transistors CF1-CF2 have different conductivity types.

Since the number of the N-type transistors and the number of the P-type transistors can be arranged in the integrated circuit 100, the integrated circuit 100 has no dummy devices.

In various embodiments, the integrated circuit 100 includes complementary field-effect transistors CF3-CF4, as shown in FIG. 1. The complementary field-effect transistor CF3 is arranged in the layer L1 and the complementary field-effect transistor CF4 is arranged in the layer L2. Alternatively stated, the complementary field-effect transistors CF3-CF4 are stacked together along z direction. Specifically, the complementary field-effect transistor CF3 includes at least two transistors T31, T33, and complementary field-effect transistor CF4 includes at least two transistors T32, T34. The at least two transistors T31, T32 are stacked with each other and respectively located on different layers L1, L2. For example, the transistors T31, T32 are stacked with each other. The transistor T31 is located on the layer L1, and the transistor T32 is located on the layer L2.

In some embodiments, the at least two transistors T33, T34 are stacked with each other and respectively located on different layers L1, L2. For example, the transistors T33, T34 are stacked with each other. The transistor T33 is located on the layer L1, and the transistor T34 is located on the layer L2 above the layer L1.

In some embodiments, the adjacent two complementary field-effect transistors CF3-CF4 share gate structures (e.g., gate structures G3-G4) extending along x-y plan. For example, as shown in FIG. 1, the gate structure G3 corresponds to gates of one of the at least two transistors T31, T32 and one of the at least two transistors T33, T34 located on the same layer. The gate structure G3 corresponds to the gate of the transistor T31 located on the layer L1 and the gate of the transistor T33 located on the layer L1. The gate structure G4 corresponds to gates of another one of the at least two transistors T31, T32 and another one of the at least two transistors T33, T34 located on the same layer. For example, the gate structure G4 corresponds to the gate of the transistor T32 located on the layer L2 and the gate of the transistor T34 located on the layer L2. In some embodiments, the gate structures G3-G4 overlap in a layout view.

In some embodiments, conductivity types of the at least two transistors T31, T32 are different. For example, the transistor T31 of the at least two transistors T31, T32 is P-type transistor, and the transistor T32 of the at least two transistors T31, T32 is N-type transistor.

In some embodiments, conductivity types of the at least two transistors T33, T34 are different. For example, the transistor T33 of the at least two transistors T33, T34 is N-type transistor, and the transistor T34 of the at least two transistors T33, T34 is P-type transistor.

In some embodiments, conductivity types of one of the at least two transistors T31, T32 and one of the at least two transistors T33, T34 located on the same layer are different. For example, the transistor T31 of the at least two transistors T31, T32 located on the layer L1 is P-type transistor, and the transistor T33 of the at least two transistors T33, T34 located on the layer L1 is N-type transistor.

In some embodiments, conductivity types of another one of the at least two transistors T31, T32 and another one of the at least two transistors T33, T34 located on the same layer are different. For example, the transistor T32 of the at least two transistors T31, T32 located on the layer L2 is N-type transistor, and the transistor T34 of the at least two transistors T33, T34 located on the layer L2 is P-type transistor.

In some embodiments, types of one of the at least two transistors T31, T32 and one of the at least two transistors T33, T34 located on different layers are the same. For example, the transistor T31 of the at least two transistors T31, T32 located on the layer L1 is P-type transistor, and the transistor T34 of the at least two transistors T33, T34 located on the layer L2 is P-type transistor. In various embodiments, the transistor T32 of the at least two transistors T31, T32 located on the layer L2 is N-type transistor, and the transistor T33 of the at least two transistors T33, T34 located on the layer L1 is N-type transistor.

With reference to FIG. 1, the complementary field-effect transistors CF1-CF2 including the gate structures G1-G2 extending vertically in Z direction are referred to as vertical complementary field-effect transistors. On contrary, the complementary field-effect transistors CF3-CF4 including the gate structures G3-G4 extending horizontally along x-y plan are referred to as horizontal complementary field-effect transistors.

As illustratively shown in FIG. 1, the integrated circuit 100 includes active areas 111-112 and 121-122. Specifically, the active areas 111-112 and 121-122 extend in y direction. The active areas 111-112 are separated along z direction and overlap with each other in a layout view accordingly to some embodiments. Similarly, the active areas 121-122 are separated along z direction and overlap with each other in the layout view accordingly to some embodiments. The gate structure G1 crosses the active areas 111-112. The gate structure G2 crosses the active areas 121-122. The gate structure G3 crosses the active areas 111 and 121. The gate structure G4 crosses the active areas 112 and 122.

The integrated circuit 100 further includes conductive segments 130 that are arranged around and coupled corresponding active areas. In some embodiments, the conductive segments 130 correspond drains/source terminals of the transistors T11-T12, T21-T22, T31-T32, and T33-T34.

The configurations of FIG. 1 are given for illustrative purposes. Various implements are within the contemplated scope of the present disclosure.

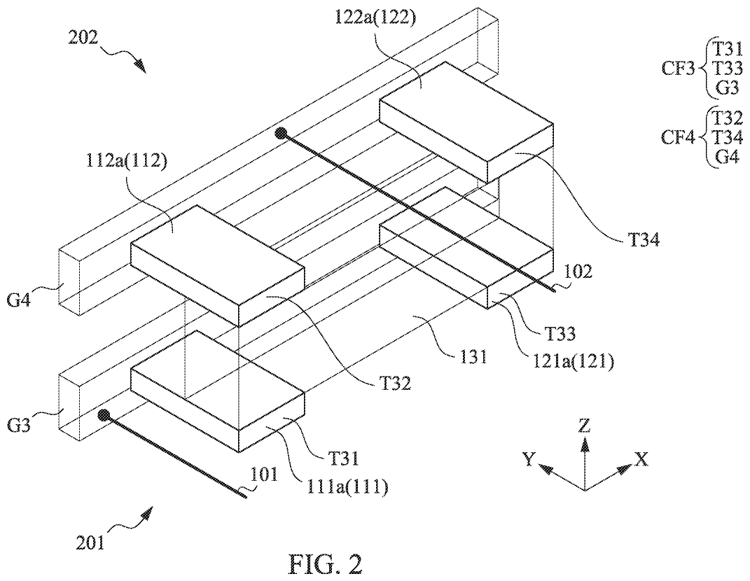

Reference is now made to FIG. 2. FIG. 2 is a schematic diagram of part of the integrated circuit 100 shown in FIG. 1, in accordance with some embodiments of the present disclosure. For illustration, the transistor T31 and the transistor T33 adopt the same gate structure G3, and the transistor T31 and the transistor T33 receive the same signal (e.g., a signal S1) from a scan line 101 through the same gate structure G3. Therefore, the transistor T31 and the transistor T33 do not have to receive different signals from different lines, and the transistor T31 and the transistor T33 only need to receive one signal from the scan line 101, such that the integrated circuit 100 reduce one line, and the interconnection of the integrated circuit 100 is simple.

The transistor T32 and the transistor T34 adopt the same gate structure G4, and the transistor T32 and the transistor T34 receive the same signal (e.g., a signal S2) from a scan line 102 through the same gate structure G4. Therefore, the transistor T32 and the transistor T34 do not have to receive different signals from different lines, and the transistor T32 and the transistor T34 only need to receive one signal from the scan line 102, such that the integrated circuit 100 reduce one line, and the interconnection of the integrated circuit 100 is simple.

In some embodiments, the scan line 101 is further coupled to a conductive trace in a metal-zero (MO) layer above the gate structure G4 for receiving the signal S1, and the scan line 102 is further coupled to another conductive trace in the metal-zero layer above the gate structure G4 for receiving the signal S2.

In some approaches, at least four conductive trace in the metal-zero layer are arranged to transmit the signals S1-S2 for a transmission gate circuit including two P-type transistors and two N-type transistors. Routing resource and front-side area in the integrated circuit are occupied accordingly.

With the configurations of the present application as shown in FIG. 2, by utilizing a swap of transistors of different conductivity types, less conductive traces, for example, two traces are necessary for signal routing in the integrated circuit 100, saving area and usage of metal trace in the structure, compared with some approaches. Correspondingly, the present application provides great flexibility for metal routing in manufacturing the integrated circuit.

Furthermore, according to some embodiments, active areas of the transistors T31-T34 are coupled together. For illustration, in FIG. 2, the integrated circuit 100 further includes a conductive structure 131 coupled to portions 111a, 112a, 121a, and 122a. In some embodiments, the portion 111a of the active area 111 corresponds to a drain/source terminal of the transistor 31. The portion 112a of the active area 112 corresponds to a drain/source terminal of the transistor 32. The portion 121a of the active area 121 corresponds to a drain/source terminal of the transistor 33. The portion 122a of the active area 122 corresponds to a drain/source terminal of the transistor 34.

The configurations of FIG. 2 are given for illustrative purposes. Various implements are within the contemplated scope of the present disclosure.

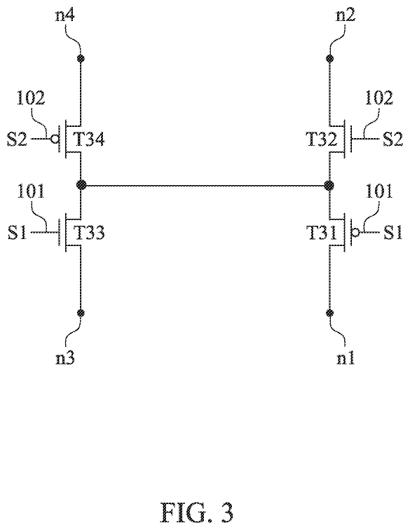

Reference is now made to FIG. 3. FIG. 3 is a circuit schematic diagram of part of the integrated circuit 100 shown in FIG. 2, in accordance with some embodiments of the present disclosure. In some embodiments, the integrated circuit 100 is implemented as a transmission gate circuit as shown in FIG. 3. For illustration, drain/source terminals of the transistors T31-T34 are coupled together. A source/drain terminal of the transistor T31 is coupled to a terminal n1. A source/drain terminal of the transistor T32 is coupled to a terminal n2. A source/drain terminal of the transistor T33 is coupled to a terminal n3. A source/drain terminal of the transistor T34 is coupled to a terminal n4. Gates of the transistors T32 and T34 are coupled to a scan line 101. Gates of the transistors T31 and T33 are coupled to a scan line 102.

As illustratively shown in the embodiments of FIG. 3, the transistor T31 and the transistor T33 receive the same signal S1 from the scan line 101, and the transistor T32 and the transistor T34 receive the same signal S2 from the line 102. For example, the transistor T31 and the transistor T33 receive the same clock signal CKB from the scan line 101, and the transistor T32 and the transistor T34 receive the same clock signal CKBB from the scan line 102. In some embodiments, the clock signal CKBB is inverted from clock signal CKB, and the clock signals CKB and CKBB have different logic states.

In operation according to some embodiments, the transistors T31-T32 are configured to be turned on in response to the signal S1 having a low logic state and the signal S2 having a high logic state to transmit a signal from/to the terminal n1 to/from the terminal n2 while the transistors T33-T34 are turned off in response to the signals S1-S2. In various embodiments, the transistors T33-T34 are configured to be turned on in response to the signal S1 having the high logic state and the signal S2 having the low logic state to transmit a signal from/to the terminal n3 to/from the terminal n4 while the transistors T31-T32 are turned off in response to the signals S1-S2.

With reference to FIGS. 1-3, a portion 111b, adjacent the portion 111a, of the active area 111 corresponds to a source of the transistor T31 of P-type and is coupled to the terminal n1. Similarly, a portion 112b, adjacent the portion 112a, of the active area 112 corresponds to a source of the transistor T32 of N-type and is coupled the terminal n2. A portion 121b, adjacent the portion 121a, of the active area 121 corresponds to a source of the transistor T33 of N-type and is coupled to the terminal n3. A portion 122b, adjacent the portion 122a, of the active area 121 corresponds to a source of the transistor T34 of P-type and is coupled to the terminal n4.

In addition, the drain/source terminals of the transistors T31-T34 are coupled together and correspond to the conductive structure 131 of FIG. 2.

In some embodiments, as shown in FIGS. 2-3, the portion 111b and the portion 121b receive/transmit the signal from/to (metal routing structure) a back side 201 of the integrated circuit 100, and the portion 112b and the portion 122b receive/transmit the signal from/to (metal routing structure) a front side 202 of the integrated circuit 100. The back side 201 and the front side 202 of the integrated circuit 100 are opposite sides with respect to the complementary field-effect transistors CF3-CF4 of FIGS. 1-3.

With reference to FIGS. 2-3 together, in some embodiments, the transistors T31-T32 are turned on to transmit, in response to the signals S1-S2, a signal that is from the back side 201 and received by the portion 111b to the portion 112b to the front side 202. Similarly, the transistors T33-T34 are turned on to transmit, in response to the signals S1-S2, a signal that is from the back side 201 and received by the portion 121b to the portion 122b to the front side 202.

In various embodiments, the transistors T31-T32 are turned on to transmit, in response to the signals S1-S2, a signal that is from the front side 202 and received by the portion 112b to the portion 111b to the back side 201. Similarly, the transistors T33-T34 are turned on to transmit, in response to the signals S1-S2, a signal that is from the front side 202 and received by the portion 122b to the portion 121b to the back side 201.

The configurations of FIG. 3 are given for illustrative purposes. Various implements are within the contemplated scope of the present disclosure. For example, in some embodiments, two conductive traces (not shown) transmitting the power supply voltages VDD and VSS for the portions 112b and 122b respectively are arranged above the gate structure G4. Conductive traces (not shown) transmitting the power supply voltages VDD and VSS for the portions 111b and 121b respectively are arranged below the gate structure G3. In another embodiment, the portion 111b, 121b, 112b, and 122b receive/transmit the signal from/to the back side 201 of the integrated circuit 100. In yet another embodiment, the portion 111b, 121b, 112b, and 122b receive/transmit the signal from/to the front side 202 of the integrated circuit 100.

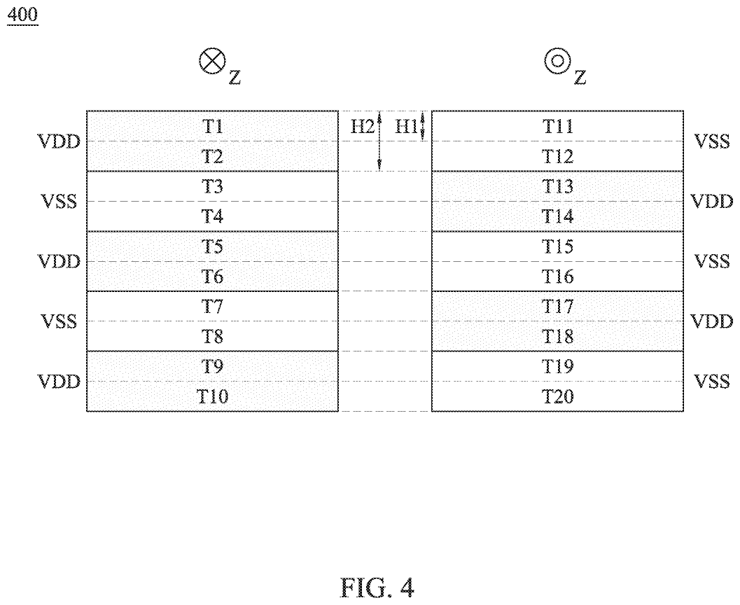

Reference is now made to FIG. 4. FIG. 4 is a top view and a bottom view diagram of part of an integrated circuit 400, in accordance with some embodiments of the present disclosure. For illustration, the integrated circuit 400 includes transistors T1-T20. In some embodiments, the transistors T1-T20 are configured with respect to the transistors T11-T12, T21-T22, and T31-T34 of FIG. 1. For example, the transistors T1-T10 overlap the transistors T11-T20. Each one of the transistors T1-T10 and corresponding one of the transistors T11-T20 form a complementary field-effect transistor and share a same gate structure, as illustratively shown in FIG. 1. For instance, the transistors T1 and T11 are included in a complementary field-effect transistor and receive a same signal at a shared gate structure thereof, and so on.

As can be seen in the left side of FIG. 4, it illustrates the top view of part of the integrated circuit 400. The transistors T1-T10 are disposed in sequent. The same type transistors can be disposed together. For example, the transistors T1, T2 are P-type transistors, the transistors T3, T4 are N-type transistors, the transistors T5, T6 are P-type transistors, the transistors T7, T8 are N-type transistors, and the transistors T9, T10 are P-type transistors.

In some embodiments, the transistors T1, T2 receive a power supply voltage VDD, the transistors T3, T4 are grounded, the transistors T5, T6 receive the power supply voltage VDD, the transistors T7, T8 are grounded, and the transistors T9, T10 receive the power supply voltage VDD. According to some embodiments, the transistors T1-T10 receive the power supply voltages VDD and VSS from a front side (e.g., the front side 202 of FIG. 2) of the integrated circuit 400 through conductive traces arranged above the transistors T1-T10 along Z direction, in which the conductive traces transmitting the power supply voltages VDD and VSS are disposed in sequent, as shown in FIG. 4. In some embodiments, the conductive traces transmitting the power supply voltage VDD overlap the transistors T1-T2, T5-T6, and T9-T10, and the conductive traces transmitting the power supply voltage VSS overlap the transistors T3-T4 and T7-T8.

In some embodiments, as can be seen in the right side of FIG. 4, it illustrates the bottom view of part of the integrated circuit 400. The transistors T11-T20 are disposed in sequent. The same type transistors can be disposed together. For example, the transistors T11, T12 are N-type transistors, the transistors T13, T14 are P-type transistors, the transistors T15, T16 are N-type transistors, the transistors T17, T18 are P-type transistors, and the transistors T19, T20 are N-type transistors.

In some embodiments, the transistors T11, T12 are grounded, the transistors T13, T14 receive the power supply voltage VDD, the transistors T15, T16 are grounded, the transistors T7, T8 receive the power supply voltage VDD, and the transistors T9, T10 are grounded. According to some embodiments, the transistors T11-T20 receive power supply voltages VDD and VSS from a back side (e.g., the back side 201 of FIG. 2), different from the front side, of the integrated circuit 400 through conductive traces arranged below the transistors T11-T20 along Z direction, in which the conductive traces transmitting the power supply voltages VDD and VSS are disposed in sequent, as shown in FIG. 4. In some embodiments, the conductive traces transmitting the power supply voltage VSS overlap the transistors T11-T12, T15-T16, and T19-T20, and the conductive traces transmitting the power supply voltage VDD overlap the transistors T13-T14 and T17-T18.

For illustration, each of the transistors T1-T20 is arranged in a cell having a cell height H1, and two adjacent transistors of a same conductivity type occupy an area having a cell height H2 in the layout view. The cell height H2 is double of the cell height H1 in some embodiment. Based on the above discussions, with the configurations of the present application as shown in FIG. 4, no white space (including dummy structure) is disposed between transistors of different conductivity types. Accordingly, area penalty issue is addressed by utilizing complementary field-effect transistor arrangements.

The configurations of FIG. 4 are given for illustrative purposes. Various implements are within the contemplated scope of the present disclosure. For example, in some embodiments and with aforementioned discussion and the reference to FIG. 4, the conductive traces for transmitting the power supply voltage VDD overlap with the conductive traces for transmitting the power supply voltage VSS.

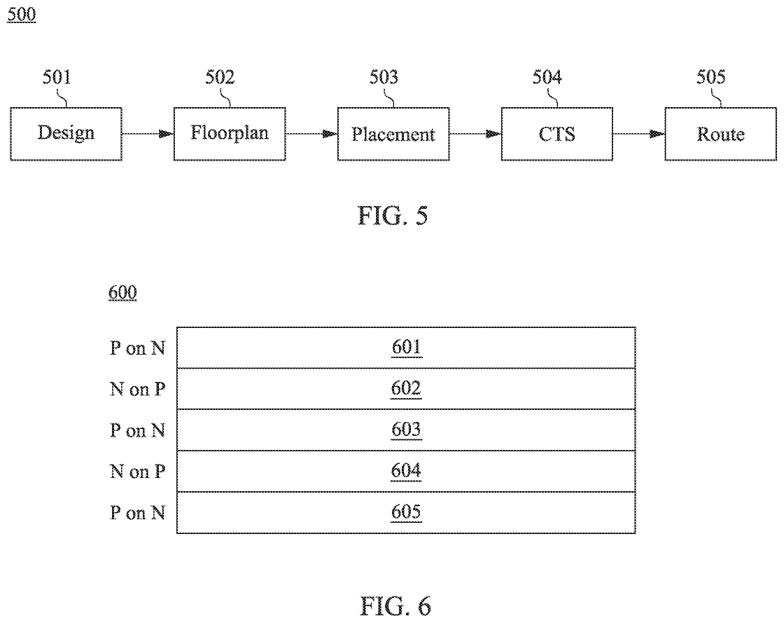

Reference is now made to FIG. 5. FIG. 5 is a block diagram illustrating of an electronic device design system 500, in accordance with one or more embodiments of the present disclosure. In some embodiments, the electronic device design system 500 is implemented in hardware, firmware, software, or any combination thereof and at least partially implemented as instructions stored on a computer-readable storage medium, which may be read and executed by one or more computer processors or processing circuitry in an electronic design automation (EDA) system.

The electronic device design system 500 includes electronic device design tools which can be used, for example, to design high-level programming descriptions of analog and/or digital circuitry for an electronic device. In some embodiments, the high-level programming descriptions can be implemented using a high-level programming language, such as C, C++, LabVIEW, MATLAB, a general purpose system design or modeling language, such as SysML, SMDL and/or SSDL, or any other suitable high-level programming language. In some embodiments, the electronic device design system 500 may include various additional features and functionalities, including, for example, one or more tools suitable to simulate, analyze, and/or verify the high-level programming descriptions of circuitry for the electronic device.

In some embodiments, the electronic device design system 500 includes a design tool 501, a floorplan (e.g., also referred to as synthesis) tool 502, a placement tool 503, a clock tree synthesis (CTS) tool 504, and a routing tool 505, each of which may be implemented at least in part as software tools accessible to and executable by one or more computing devices, processors or the like.

Referring to FIG. 5, a high-level design of the integrated circuit provided by a circuit designer is obtained by the design tool 501. In some embodiments, a gate-level netlist is generated through logic synthesis based on the high-level design and gates in the gate-level netlist are mapped to available cells in a standard cell library. The term “netlist” used herein refers to graphical-based representation such as a schematic or a text-based representation of a circuit or both. In electronic design, a netlist is a description of the connectivity of an electronic circuit. A single netlist is effectively a collection of several related lists. In its simplest form, a netlist consists of a list of the terminals (“pins”) of electronic components in a circuit and a list of electrical conductors that interconnect the terminals. A net is a conductor that interconnects two or more component terminals.

The floorplan tool 502 in the electronic device design system 500 is operable to generate and optimize floorplan layouts after floorplan synthesis has been performed (which may be referred to herein as a floorplan design) for an electrical device before placement of the floorplan layout. The floorplan tool 502 places blocks or macros in a chip area or core area in the electronic device design according to a predetermined floorplan specification (e.g., sizes and locations of blocks or macros), a predetermined power consumptions specification (e.g., a sum of total cells' estimated power in blocks or macros), or/and a predetermined bump plan specification (e.g., bump assignment including domains, center locations, types of bumps that are contact structures configured to transmit supply voltages to cells) on a floorplan layout. In some embodiments, the floorplan tool also translates one or more characteristics, parameters of features of floorplan layout, or attributes of the electronic device into one or more logic operations, one or more arithmetic operations, one or more control operations, or the like, which may then be translated into the high-level programming descriptions in terms of the analog circuitry and/or the digital circuitry.

Specifically, with reference to FIG. 6 illustrating a schematic diagram of part of a floor plan of an integrated circuit, in accordance with some embodiments. The floorplan tool 502 provides a hybrid row structure for N-type and P-type transistors, in which N-type and P-type transistors are arranged in sequence in adjacent rows of the hybrid row structure, and further divides cells including N-type transistors with cells including P-type transistors into different rows.

For example, as shown in FIG. 6, cells including complementary field-effect transistors (e.g., the complementary field-effect transistor CFET2 of FIG. 1), each having a P-type transistor stacked on an N-type transistor, are arranged in rows 601, 603, and 605. Cells including complementary field-effect transistors (e.g., the complementary field-effect transistor CFET1 of FIG. 1), each having an N-type transistor stacked on a P-type transistor, are arranged in rows 602 and 604. The rows 601, 603, and 605 and the rows 602, 604 are interlaced with each other.

The placement tool 503 generates detailed configurations of cells which correspond to, or otherwise implement, the one or more logic operations, one or more arithmetic operations, one or more control operations, or the like produced by the floorplan tool 502. The cells may include geometric shapes which correspond to various features of semiconductor devices, including, for example, diffusion layers, polysilicon layers, metal layers, and/or interconnections between layers.

In some embodiments, the geometric shapes for some of the analog circuitry and/or the digital circuitry can be defined in accordance with a standard cell from among a predefined library of standard cells associated with a technology library. The standard cell represents one or more semiconductor devices as well as their interconnection structures that are configured and arranged to provide a logical function, such as AND, OR, XOR, XNOR, or NOT, or a storage function, such as a flipflop or a latch. The predefined library of standard cells may be defined in terms of geometric shapes which correspond to diffusion layers, polysilicon layers, metal layers, and/or interconnections between layers. Thereafter, the placement tool 503 assigns locations for the geometric shapes on a printed circuit board (PCB) and/or a semiconductor substrate.

The CTS tool 504 performs clock tree synthesis (CTS) on a design generated, for example, by the placement tool 503. Clock tree synthesis generally refers to a process of synthesizing a clock tree to achieve zero or minimal skew and insertion delay, and includes inserting clock tree cells which correspond to, or otherwise implement, clock operations for the electronic device. The clock cells may include geometric shapes which correspond to circuitry or logical devices which implement clock features of semiconductor devices, including, for example, buffers, inverters, or the like. In some embodiments, each of the clock tree cells includes one or more buffers or inverters electrically positioned along clock paths of the electronic device design. Further, in some embodiments, one or more of the clock cells may include clock gating cells, such as integrated clock gating cells (ICGs). Clock gating is a common technique for reducing clock power by shutting off the clock to modules or circuit components by utilizing a clock enable signal, and such clock gating may be implemented using integrated clock gating cells. Integrated clock gating cells may include one or more logical circuit elements, such as an OR gate, an AND gate, or a latch.

The routing tool 505 produces physical interconnections between the cells or the geometric shapes in the layout provided by the placement tool 503, for example, after clock tree synthesis has been performed on the layout by the CTS tool 504. In some embodiments, the routing tool 505 utilizes a textual or an image-based netlist describing the analog circuitry, the digital circuitry, the technology library, a semiconductor foundry for fabricating the electronic device and/or a semiconductor technology node for fabricating the electronic device to assign the interconnections between the geometric shapes.

The electronic device design system 500 may include a variety of additional tools, including, for example, a verification tool. The verification tool may perform various verifications or checks on an electronic device layout, e.g., after placement, CTS, and routing. For example, in some embodiments, the verification tool can analyze the electronic device layout and can provide a static timing analysis (STA), a SIR analysis, also referred to an IREM analysis, a Clock Domain Crossing Verification (CDC check), a formal verification, also referred to as model checking, equivalence checking, or any other suitable analysis and/or verification. In some embodiments, the verification tool can perform an alternating current (AC) analysis, such as a linear small-signal frequency domain analysis, and/or a direct current (DC) analysis, such as a nonlinear quiescent point calculation or a sequence of nonlinear operating points calculated while sweeping a voltage, a current, and/or a parameter to perform the STA, the IREM analysis, or the like.

Based on the discussion above, the present application provides an integrated circuit. Since the number of one type transistors and the number of another type transistors can be arranged in the integrated circuit, the integrated circuit has no dummy devices. The transistors on the same layer do not have to receive different signals from different lines, and the transistors only need to receive one signal from the same line, such that the integrated circuit reduce one line, and the interconnection of the integrated circuit is simple.

According to some embodiments of the present disclosure, an integrated circuit is provided which includes a first complementary field-effect transistor and a second complementary field-effect transistor. The first complementary field-effect transistor includes at least two first transistors respectively located on a first layer and a second layer. The second complementary field-effect transistor is disposed adjacent to the first complementary field-effect transistor. The second complementary field-effect transistor includes at least two second transistors respectively located on the first layer and the second layer. Type of one of the at least two first transistors located on the first layer is different from type of one of the at least two second transistors located on the first layer.

According to some embodiments of the present disclosure, an integrated circuit is provided which includes at least two first transistors, at least two second transistors, and a first gate structure. The at least two first transistors are stacked with each other and respectively located on different layers. The at least two second transistors are stacked with each other and respectively located on different layers. One of the at least two first transistors or one of the at least two second transistors located on a same layer is turned off in response to a first signal received by a first gate structure shared by the one of the at least two first transistors and the one of the at least two second transistors.

According to some embodiments of the present disclosure, an integrated circuit is provided which includes a first transistor, a second transistor, a third transistor, and a fourth transistor. The first transistor has a first drain/source terminal coupled to a first terminal and is located on a first layer. The second transistor includes a first drain/source terminal connected to a second drain/source terminal of the first transistor and a second drain/source terminal connected to a second terminal and is stacked with the first transistor and located on a second layer being different from the first layer, wherein type of the first transistor is different from type of the second transistor. The third transistor has a first drain/source terminal coupled to a third terminal and a second drain/source terminal coupled to the first drain/source terminal of the second transistor and the second drain/source terminal of the first transistor. The third transistor is disposed adjacent to the first transistor and located on the first layer. Type of the third transistor is different from type of the first transistor. The fourth transistor has a first drain/source terminal coupled to a fourth terminal and a second drain/source terminal coupled to the first drain/source terminal of the second transistor and the second drain/source terminal of the first transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a first complementary field-effect transistor comprising:
at least two first transistors respectively located on a first layer and a second layer; and
a second complementary field-effect transistor disposed adjacent to the first complementary field-effect transistor, wherein the second complementary field-effect transistor comprises:
at least two second transistors respectively located on the first layer and the second layer, wherein type of one of the at least two first transistors located on the first layer is different from type of one of the at least two second transistors located on the first layer.

2. The integrated circuit of claim 1, wherein type of another one of the at least two first transistors located on the second layer is different from type of another one of the at least two second transistors located on the second layer.

3. The integrated circuit of claim 2, wherein type of one of the at least two first transistors located on the first layer is a same as type of another one of the at least two second transistors located on the second layer.

4. The integrated circuit of claim 3, wherein type of another one of the at least two first transistors located on the second layer is a same as type of one of the at least two second transistors located on the first layer.

5. The integrated circuit of claim 1, wherein the first complementary field-effect transistor further comprises:
a first gate structure shared by the at least two first transistors.

6. The integrated circuit of claim 5, wherein the second complementary field-effect transistor further comprises:
a second gate structure shared by the at least two second transistors.

7. The integrated circuit of claim 1, wherein types of the at least two first transistors are different.

8. The integrated circuit of claim 7, wherein types of the at least two second transistors are different.

9. An integrated circuit, comprising:
at least two first transistors stacked with each other and respectively located on different layers; and
at least two second transistors stacked with each other and respectively located on different layers,
wherein one of the at least two first transistors or one of the at least two second transistors located on a same layer is configured to be turned off in response to a first signal received by a first gate structure shared by the one of the at least two first transistors and the one of the at least two second transistors.

10. The integrated circuit of claim 9, wherein another one of the at least two first transistors and another one of the at least two second transistors located on a same layer have a second gate structure configured to receive a second signal different from the first signal.

11. The integrated circuit of claim 10, wherein the at least two first transistors are configured to transmit, in response to the first and second signals, a third signal received from a first side of the integrated circuit to a second side of the integrated circuit.

12. The integrated circuit of claim 9, wherein types of the at least two first transistors are different from each other, and types of the at least two second transistors are different from each other.

13. The integrated circuit of claim 9, wherein types of one of the at least two first transistors and one of the at least two second transistors located on a same layer are different from each other.

14. The integrated circuit of claim 13, wherein types of another one of the at least two first transistors and another one of the at least two second transistors located on a same layer are different from each other.

15. The integrated circuit of claim 9, wherein types of one of the at least two first transistors and one of the at least two second transistors located on different layers are the same as each other.

16. An integrated circuit, comprising:
a first transistor that has a first drain/source terminal coupled to a first terminal and is located on a first layer;
a second transistor that includes a first drain/source terminal connected to a second drain/source terminal of the first transistor and a second drain/source terminal connected to a second terminal and is stacked with the first transistor and located on a second layer being different from the first layer, wherein type of the first transistor is different from type of the second transistor;
a third transistor that has a first drain/source terminal coupled to a third terminal and a second drain/source terminal coupled to the first drain/source terminal of the second transistor and the second drain/source terminal of the first transistor, wherein the third transistor is disposed adjacent to the first transistor and located on the first layer, wherein type of the third transistor is different from type of the first transistor; and
a fourth transistor that has a first drain/source terminal coupled to a fourth terminal and a second drain/source terminal coupled to the first drain/source terminal of the second transistor and the second drain/source terminal of the first transistor.

17. The integrated circuit of claim 16, wherein the first transistor and the second transistor comprise a first gate structure.

18. The integrated circuit of claim 17, further comprising:
a fifth transistor connected to the first transistor and located on the first layer, wherein type of the first transistor is a same as type of the fifth transistor; and
a sixth transistor connected to the third transistor and located on the first layer, wherein type of the third transistor is a same as type of the sixth transistor.

19. The integrated circuit of claim 18, wherein the fifth transistor and the sixth transistor comprise a second gate structure.

20. The integrated circuit of claim 18, wherein type of the fifth transistor is different from type of the sixth transistor.
